(19) United States
(12) Patent Application Publication
(10) Pub. No.: US 2025/0219615 A1
(43) Pub. Date: Jul. 3, 2025

(54) BULK ACOUSTIC WAVE RESONATOR WITH BRAGG GRATING EMBEDDED IN ELECTRODE

(71) Applicant: SKYWORKS GLOBAL PTE LTD., Singapore (SG)

(72) Inventors: Benjamin Paul Abbott, Irvine, CA (US); Alexandre Augusto Shirakawa, Cardiff by the Sea, CA (US); David Albert Feld, Los Altos, CA (US); Stefan Bader, Fort Collins, CO (US); Kwang Jae Shin, Yongin-si (KR)

(21) Appl. No.: 18/983,830

(22) Filed: Dec. 17, 2024

Related U.S. Application Data
(60) Provisional application No. 63/617,124, filed on Jan. 3, 2024.

(51) Int. Cl. H03H 9/17; H03H 9/13; H03H 9/56

(52) U.S. Cl. CPC H03H 9/175; H03H 9/131; H03H 9/568

(57) ABSTRACT

Aspects and embodiments disclosed herein include a bulk acoustic wave resonator comprising a layer of piezoelectric material and one of a top electrode disposed on top of the layer of piezoelectric material or a bottom electrode disposed on a bottom of the layer of piezoelectric material, the one of the top electrode or the bottom electrode including a Bragg pair having alternating layers of a first metal and a second metal.

### CROSS-REFERENCE TO RELATED APPLICATIONS

This application claims priority under 35 U.S.C. § 119(e) to U.S. Provisional Patent Application Ser. No. 63/617,124, titled “BULK ACOUSTIC WAVE RESONATOR WITH BRAGG GRATING EMBEDDED IN ELECTRODE,” filed Jan. 3, 2024, the entire content of which is incorporated by reference herein for all purposes.

### BACKGROUND

### Technical Field

Embodiments of this disclosure relate to bulk acoustic wave resonators and to acoustic wave filters, electronic modules, and electronic devices including same.

### Description of Related Technology

Acoustic wave filters can filter radio frequency signals. An acoustic wave filter can include a plurality of acoustic wave resonators arranged to filter a radio frequency signal. The resonators can be arranged as a ladder circuit. Example acoustic wave resonators include surface acoustic wave (SAW) resonators and bulk acoustic wave (BAW) resonators. A film bulk acoustic resonator is an example of a BAW resonator. A solidly mounted resonator (SMR) is another example of a BAW resonator.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a bulk acoustic wave resonator. The bulk acoustic wave resonator comprises a layer of piezoelectric material, one of a top electrode disposed on top of the layer of piezoelectric material or a bottom electrode disposed on a bottom of the layer of piezoelectric material, the one of the top electrode or the bottom electrode including a Bragg pair having alternating layers of a first metal and a second metal.

In some embodiments, the Bragg pair is disposed directly on the one of the top of the layer of piezoelectric material or the bottom of the layer of piezoelectric material.

In some embodiments, a first Bragg pair is disposed directly on the top of the layer of piezoelectric material and a second Bragg pair is disposed directly on the bottom of the layer of piezoelectric material.

In some embodiments, the first metal layer of the Bragg pair is disposed directly on the one of the top of the layer of piezoelectric material or directly on the bottom of the layer of piezoelectric material and the second metal layer of the Bragg pair is disposed on a side of the first metal layer opposite the layer of piezoelectric material, the first metal layer having a higher acoustic impedance than the second metal layer.

In some embodiments, the first metal layer is formed of one of W, Ru, Pt, Mo, Jr, Os, or an alloy thereof.

In some embodiments, the second metal layer is formed of one of Al, Ti, Sc, Zr, Y, V, Nb, Be, or an alloy thereof.

In some embodiments, the first metal layer of the Bragg pair is disposed directly on the one of the top of the layer of piezoelectric material or directly on the bottom of the layer of piezoelectric material and the second metal layer of the Bragg pair is disposed on a side of the first metal layer opposite the layer of piezoelectric material, the first metal layer having a lower acoustic impedance than the second metal layer.

In some embodiments, the first metal layer is formed of one of Al, Ti, Sc, Zr, Y, V, Nb, Be, or an alloy thereof.

In some embodiments, the second metal layer is formed of one of W, Ru, Pt, Mo, Jr, Os, or an alloy thereof.

In some embodiments, the Bragg pair has an acoustic length of between about λ/3 and about 2λ/3, λ being a wavelength of a main acoustic wave generated in the bulk acoustic wave resonator at a series resonance frequency of the bulk acoustic wave resonator.

In some embodiments, the layer of the first metal has a same acoustic length as the layer of the second metal.

In some embodiments, the layer of the first metal has a different acoustic length than the layer of the second metal.

In some embodiments, the bulk acoustic wave resonator further comprises an innermost top metal electrode layer disposed directly on top of the piezoelectric material layer, the Bragg pair being a first Bragg pair disposed on top of the innermost top metal electrode layer.

In some embodiments, the bulk acoustic wave resonator further comprises an innermost bottom metal electrode layer disposed directly on a bottom surface of the piezoelectric material layer and a second Bragg pair disposed below the innermost bottom metal electrode layer.

In some embodiments, the first layer of metal of the first Bragg pair is an intermediate top metal electrode layer and has a lower acoustic impedance than the innermost top metal electrode layer.

In some embodiments, the second layer of metal of the first Bragg pair is an uppermost top metal electrode layer and has a higher acoustic impedance than the intermediate top metal electrode layer.

In some embodiments, the intermediate top metal electrode layer is formed of one of Al, Ti, Sc, Zr, Y, V, Nb, Be, or an alloy thereof.

In some embodiments, the uppermost top metal electrode layer is formed of one of W, Ru, Pt, Mo, IR, Os, or an alloy thereof.

In some embodiments, the uppermost top metal electrode layer is formed of a same metal as the innermost top metal electrode layer.

In some embodiments, the uppermost top metal electrode layer is formed of a different metal than the innermost top metal electrode layer.

In some embodiments, the first layer of metal of the second Bragg pair is an intermediate bottom metal electrode layer and has a lower acoustic impedance than the innermost bottom metal electrode layer.

In some embodiments, the second layer of metal of the second Bragg pair is a lowermost bottom metal electrode layer and has a higher acoustic impedance than the intermediate bottom metal electrode layer.

In some embodiments, the intermediate bottom metal electrode layer is formed of one of Al, Ti, Sc, Zr, Y, V, Nb, Be, or an alloy thereof.

In some embodiments, the lowermost bottom metal electrode layer is formed of one of W, Ru, Pt, Mo, Jr, Os, or an alloy thereof.

In some embodiments, the lowermost bottom metal electrode layer is formed of a same metal as the innermost bottom metal electrode layer.

In some embodiments, the lowermost bottom metal electrode layer is formed of a different metal than the innermost bottom metal electrode layer.

In some embodiments, each of the first and second metal layers of each of the first and second Bragg pairs have acoustic lengths greater than either of the innermost top metal electrode layer or the innermost bottom electrode layer.

In some embodiments, the one of the top electrode or the bottom electrode includes a plurality of Bragg pairs, each of the plurality of Bragg pairs having alternating layers of a first metal and a second metal.

In some embodiments, each of the top electrode and the bottom electrode includes a plurality of Bragg pairs, each of the plurality of Bragg pairs having alternating layers of a first metal and a second metal.

In some embodiments, each of the top electrode and the bottom electrode includes a layer of Al with a thickness greater than the skin depth of Al disposed on a side of the plurality of Bragg pairs opposite the layer of piezoelectric material.

In some embodiments, the one of the top electrode or the bottom electrode includes a layer of Al with a thickness greater than the skin depth of Al disposed on a side of the plurality of Bragg pairs opposite the layer of piezoelectric material.

In some embodiments, the bulk acoustic wave resonator is configured as a film bulk acoustic wave resonator.

In some embodiments, the bulk acoustic wave resonator is configured as a solidly mounted resonator.

In some embodiments, the bulk acoustic wave resonator is included in an acoustic wave filter.

In some embodiments, the acoustic wave filter is included in an electronics module. In some embodiments, the electronics module is included in an electronic device.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a cross-sectional view of an example of a solidly mounted resonator;

FIG. 3 is an example of a stack of material layers making up a piezoelectric material layer and upper and/or lower electrodes of a bulk acoustic wave resonator;

FIG. 4A is a table of selected material properties of various metals and of silicon dioxide;

FIG. 4B is a chart of the resistivity of various metals as a function of metal layer thickness;

FIG. 5 is another example of a stack of material layers comprising a piezoelectric layer sandwiched between two sets of electrodes which form a bulk acoustic wave resonator;

FIG. 6 illustrates an example of a radio frequency filter;

FIG. 7 illustrates an embodiment of an electronics module;

FIG. 8 illustrates an example of a front-end module which may be used in an electronic device; and

FIG. 9 illustrates an example of an electronic device.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally include a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined, in part, by the thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

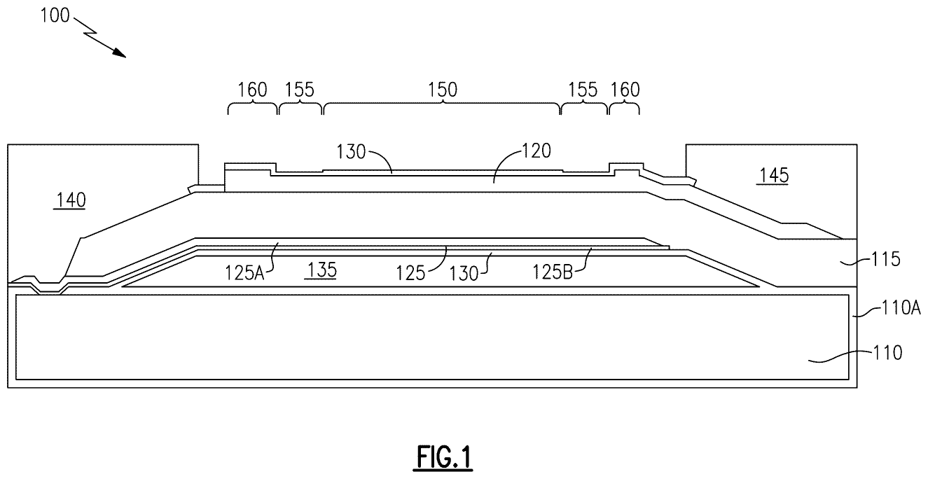

FIG. 1 is cross-sectional view of an example of a film bulk acoustic wave resonator, indicated generally at 100. The film bulk acoustic wave resonator 100 is disposed on a substrate 110, for example, a silicon substrate that may include a dielectric surface layer 110A of, for example, silicon dioxide. The film bulk acoustic wave resonator 100 includes a layer or film of piezoelectric material 115, for example, aluminum nitride (AlN), scandium-doped aluminum nitride (AlScₓN₁₋ₓ), or another suitable piezoelectric material. A top electrode 120 is disposed on top of a portion of the layer or film of piezoelectric material 115 and a bottom electrode 125 is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 including a main active domain in the layer or film of piezoelectric material 115 in which a main acoustic wave is excited during operation. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The material layer 130 in the recessed frame region(s) 155 is typically etched during manufacturing to achieve a desired difference in acoustic velocity between the central region 150 and the recessed frame region(s) 155. Accordingly, the dielectric material layer 130 initially deposited in both the central region 150 and recessed frame region(s) 155 is deposited with a sufficient thickness that allows for etching of sufficient dielectric material in the recessed frame region(s) 155 to achieve a desired difference in thickness of the dielectric material layer 130 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

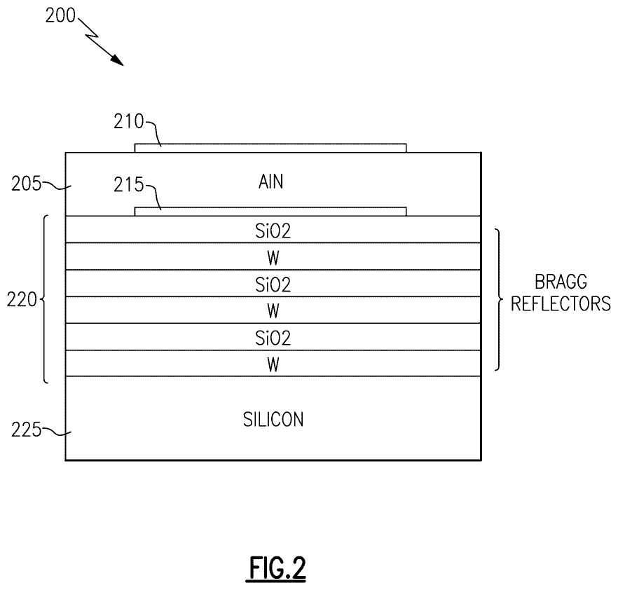

Another form of BAW resonator is a solidly mounted resonator (SMR). An example of an SMR is illustrated generally at 200 in FIG. 2. As illustrated, the SMR 200 includes a piezoelectric material layer 205, an upper electrode 210 on the piezoelectric material layer 205, and a lower electrode 215 on a lower surface of the piezoelectric material layer 205. The piezoelectric material layer 205 can be an aluminum nitride layer or a scandium-doped aluminum nitride layer, or a layer of another suitable piezoelectric material. The lower electrode 215 can be grounded in certain instances. In some other instances, the lower electrode 215 can be floating. Bragg reflectors 220 are disposed between the lower electrode 215 and a semiconductor substrate 225. The semiconductor substrate 225 can be a silicon substrate. Any suitable Bragg reflectors can be implemented. For example, the Bragg reflectors can be SiO₂/W.

It should be appreciated that the BAW resonators illustrated in the figures are illustrated in a highly simplified form. The relative dimensions of the different features are not shown to scale. Further, typical BAW resonators may include additional features or layers not illustrated.

Moving towards higher frequencies beyond 5 GHz, film bulk acoustic wave resonator piezoelectric material layers and electrodes in BAW resonators become very thin resulting in increased electrical resistance in the electrodes. This may cause insertion loss deterioration, reduced quality factor, limited power handling capabilities, and reduced yield.

Aspects and embodiments disclosed herein involve the use of multiple layers of metals for the electrodes of a BAW resonator instead of a single metal layer. The multilayer stack of metals forms a Bragg reflector (mirror) that confines the acoustic energy to the piezoelectric material layer and first few layers of the reflector. The multilayer stack of metals may also result in electrodes with increased conductivity as compared to conventional BAW electrodes. Metal layers forming the mirror should have a large mismatch in acoustic impedance and should be sized to yield highest reflection at the frequency of operation of the resonator. Metal layers forming the mirror should have low resistivity to enhance the conductance of the electrodes. Metal layers formed of metals such as ruthenium and tungsten, having high acoustic impedances, and aluminum or titanium, having low acoustic impedances and high conductivities, that are already available in many BAW resonator fabrication processes can be used to build the metallic electrode/mirror. The metallic mirror results in better resonator quality factor and lower electrode resistance which means better filter insertion loss. Moreover, the metallic mirror provides a thermal path which improves the power handling and ruggedness of BAW filters. In various embodiments, a metallic mirror formed of two layers of different metals may perform better when the innermost (closest to the piezoelectric material layer) metal layer has a lower acoustic impedance than the outermost metal layer as compared to a metallic mirror in which the innermost metal layer had a higher acoustic impedance than the outermost metal layer. Metallic mirrors as disclosed herein may be utilized as or within an upper and/or a lower electrode of a BAW. In some embodiments a metallic mirror as disclosed herein may be utilized as or within only one of the electrodes of a BAW.

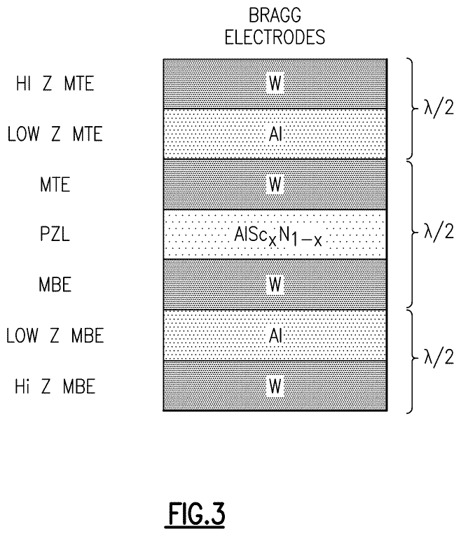

One example of an electrode material stack that may be utilized as either the top and/or bottom electrodes 125, 130, respectively, of a film bulk acoustic wave resonator or as the upper electrode and/or bottom electrode 210, 215 of a SMR is illustrated in FIG. 3. The electrode material stack includes a metal top electrode (MTE), also referred to herein as an innermost top metal electrode layer, and a metal bottom electrode (MBE), also referred to herein as an innermost bottom metal electrode layer, disposed on the top and bottom, respectively, of a layer of piezoelectric material (PZL). In the example of FIG. 3 the metal top electrode and metal bottom electrode are each formed of a high acoustic impedance metal, illustrated as tungsten, but may be formed of other high acoustic impedance metals or alloys. The layer of piezoelectric material is illustrated as scandium-doped aluminum nitride but may be formed of any other suitable piezoelectric material.

A layer of a metal with a lower acoustic impedance than the metal top electrode is disposed on the top of the metal top electrode to form a low impedance metal top electrode layer (Low Z MTE). A layer of a metal with a lower acoustic impedance than the metal bottom electrode is disposed on the bottom of the metal bottom electrode to form a low impedance metal bottom electrode layer (Low Z MBE). The Low Z MTE layer may be referred to herein as an intermediate top metal electrode layer. The Low Z MBE layer may be referred to herein as an intermediate bottom metal electrode layer. Both the low impedance metal top electrode layer and the low impedance metal bottom electrode layer are illustrated as being aluminum but may in other embodiments be another type of low acoustic impedance metal or alloy.

A layer of a metal with a higher acoustic impedance than the metal of the low impedance metal top electrode is disposed on the top of the low impedance metal top electrode to form a high impedance metal top electrode layer (High Z MTE). A layer of a metal with a higher acoustic impedance than the metal of the low impedance metal bottom electrode is disposed on the bottom of the low impedance metal bottom electrode to form a high impedance metal bottom electrode layer (High Z MBE). The High Z MTE layer may be referred to herein as an uppermost top metal electrode layer. The High Z MBE layer may be referred to herein as a lowermost bottom metal electrode layer. Both the high impedance metal top electrode layer and the high impedance metal bottom electrode layer are illustrated as being tungsten, but may in other embodiments be another type of high acoustic impedance metal or alloy.

The electrode material stack may utilize the same metals for the MTE and the High Z MTE and for the MBE and High Z MBE but in other embodiments, different metals may be used for different ones of these metal layers. The electrode material stack of FIG. 3 is illustrated as being vertically symmetric with the same sequence of metal layers on top of and below the piezoelectric material layer, but in other embodiments may be asymmetric with different metal layers or sequences of metal layers (or even no metal layers) on top of and below the piezoelectric material layer.

Electrode material stacks such as illustrated in FIG. 3 may result in a lower piezoelectric coupling coefficient as compared to electrode structures utilizing only the MTE and MBE due to more mechanical energy being stored in the additional electrode material layers. This effect can be reduced by selecting the thickness of the metal layers to effectively reflect mechanical energy back into the piezoelectric material layer. Accordingly, as shown in FIG. 3, the piezoelectric material layer, MBE, and MTE may together have a thickness, also referred to as “acoustic length” herein, of about λ/2 where λ is the wavelength of the main acoustic wave generated in the bulk acoustic wave resonator at the series resonance frequency fₛ of the BAW resonator. Either of the MBE or MTE may have a thickness (or acoustic length) of about λ/6 or less. The combination of the Low Z MTE and High Z MTE may have a thickness (or acoustic length) of about λ/2, thus forming a Bragg reflector or Bragg grating, also referred to herein as a Bragg pair. The combination of the Low Z MBE and High Z MBE may have a thickness (or acoustic length) of about λ/2, thus forming another Bragg pair. In some embodiments, each of the Low Z MTE and High Z MTE may have the same or substantially the same thickness (or acoustic length) of about λ/4 but in other embodiments may have different thicknesses (or acoustic lengths). In some embodiments, each of the Low Z MBE and High Z MBE may have the same or substantially the same thickness (or acoustic length) of about λ/4 but in other embodiments may have different thicknesses (or acoustic lengths). Any one or more of the Low Z MBE, High Z MBE, Low Z MTE, or High Z MTE may range in thickness (or acoustic length) from about λ/8 to about 3λ/8. In some embodiments the combined thickness (or acoustic length) of the Low Z MBE and the High Z MBE and/or the combined thickness (or acoustic length) of the Low Z MTE and the High Z MTE may range from about λ/3 to about 2λ/3 or from about 3λ/8 to about 5λ/8.

In some embodiments, if the lower electrode 215 of a SMR includes a Bragg pair as disclosed herein it may be possible to eliminate the Bragg reflectors 220 and still obtain acceptable performance.

Different metals may exhibit different acoustic velocities, so if one were to select a particular metal for any of the Bragg pair metal layers one could determine a thickness t of λ/4 for the Bragg pair metal layer from equation (1) below:

$$t = \frac{\sqrt{{c}_{33} / ρ}}{4 \cdot {f}_{s}} \qquad ( 1 )$$

where c₃₃ is the vertical modulus, and p is the density of the electrode layer.

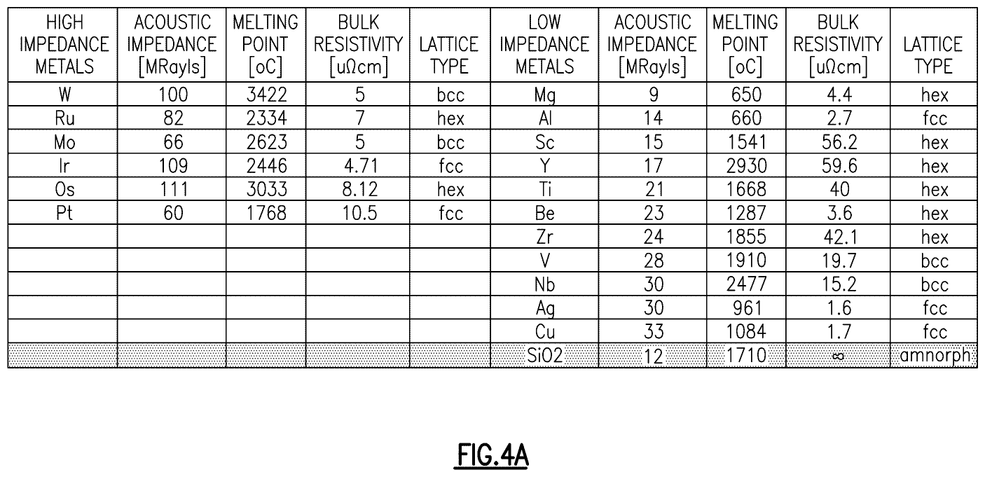

Larger relative differences in acoustic impedance of the metals of the Bragg pair layers will produce a larger electromechanical coupling coefficient. The Bragg pair layers should also be formed of metals with high conductivities, so there may in some instances be a tradeoff between acoustic impedance and conductivity when selecting metals for the Bragg pair layers. The acoustic impedances and electrical resistivities of several selected high impedance metals and low impedance metals as well as silicon dioxide are shown in the table of FIG. 4A. Any of the metals listed as “High Impedance Metals” in FIG. 4A may be used as a high impedance metal layer in a Bragg pair as disclosed herein and any of the metals listed as “Low Impedance Metals” in FIG. 4A may be used as a low impedance metal layer in a Bragg pair as disclosed herein. From FIG. 4A it can be seen that Al and W have one of the highest acoustic mismatches in metals. W, Ru, Pt, and Mo each have high acoustic impedances and reasonable resistivities and thus may be used as the high impedance layers in Bragg pairs. Ti and Al each have low acoustic impedances and low resistivities and thus may be used as the low impedance layers in Bragg pairs. An alloy of Al and Ti may also be suitable for use as a low impedance layer in a Bragg pair.

FIG. 4B is a chart of the resistivity of various metals as a function of metal layer thickness. From this chart it can be seen that both tungsten and aluminum layers have low resistivities even when as thin as 50 nm, thus making them potentially good choices for high and low impedance metals, respectively, for use in Bragg pairs in an electrode of a BAW resonator.

Simulations were performed to evaluate the effect on electromechanical coupling coefficient (kₜ²) and series resistance (Rₛ) of different metal layers or stacks of metal layers for upper and lower electrodes of a film bulk acoustic wave resonator. In addition to the metal layers discussed above, the uppermost metal layers in the electrodes were simulated as being covered by a trimming/passivation layer (SV) of SiO₂ disposed on top of the adhesion layer. The lowermost metal layers in the electrodes were simulated as having a passivation/etch stop layer (MEM) of SiO₂ disposed on their lower sides.

The results of simulations of film bulk acoustic wave resonator structures with single metal layers of different types utilized for the upper and lower electrodes are presented in Table 1 below. In Table 1 as well as the tables that follow, the term “MTE1” refers to the electrode layer directly on top of the piezoelectric material layer (the innermost top metal electrode layer), the term “MTE2” refers to the electrode layer (when present) directly on top of the MTE1 metal layer, and the term “MTE3” refers to the electrode layer (when present) directly on top of the MTE2 metal layer. The term “MBE3” refers to the electrode layer directly below the piezoelectric material layer (the innermost bottom electrode layer), the term “MBE2” refers to the electrode layer (when present) directly below the MBE3 metal layer, and the term “MBE1” refers to the electrode layer (when present) directly below the MBE2 metal layer. Since Table 1 includes examples of electrodes with only single metal layers, there are no MTE2, MTE3, MBE2, or MBE1 layers.

TABLE 1
Properties of electrodes with single metal layers

| | Sample No. | | | | |
|---|---|---|---|---|---|
| | 1 | 2 | 3 | 4 | 5 |
| SV | SiO₂ | SiO₂ | SiO₂ | SiO₂ | SiO₂ |
| MTE3 | | | | | |
| MTE2 | | | | | |
| MTE1 | Al | Ru | W | Ru | W |
| PZL | AlScN | AlScN | AlScN | AlScN | AlScN |
| MBE3 | Al | Ru | W | AI | Al |
| MBE2 | | | | | |
| MBE1 | | | | | |
| MEM | SiO₂ | SiO₂ | SiO₂ | SiO₂ | SiO₂ |
| kₜ² (%) | 21.1 | 22.2 | 22.3 | 20.9 | 20.9 |
| Rₛ (Ω/□) | 3.54 | 2.34 | 2.02 | 1.1 | 0.84 |

The results of simulations of film bulk acoustic wave resonator structures with two metal layers of different types configured as Bragg pairs utilized for the upper and lower electrodes are presented in Table 2 below in which the acronyms have the same meanings as in Table 1. In the examples shown in FIG. 2 there may be no thin innermost top metal electrode layer or innermost bottom electrode layer, and the MTE2 and MBE3 layers may be disposed directly on the piezoelectric material layer.

TABLE 2
Properties of electrodes with two metal layers

| | Sample No. | | | |
|---|---|---|---|---|
| | 6 | 7 | 8 | 9 |
| SV | SiO₂ | SiO₂ | SiO₂ | SiO₂ |
| MTE3 | Al | Al | Ru | W |
| MTE2 | Ru | W | Al | Al |
| MTE1 | | | | |
| PZL | AlScN | AlScN | AlScN | AlScN |
| MBE3 | | | | |
| MBE2 | Ru | W | Al | |
| MBE1 | Al | Al | Ru | W |
| MEM | SiO₂ | SiO₂ | SiO₂ | SiO₂ |
| kₜ² (%) | 12.5 | 12.7 | 12.5 | 12.7 |
| Rₛ (Ω/□) | 0.06 | 0.06 | 0.06 | 0.06 |

The results of simulations of film bulk acoustic wave resonator structures with two metal layers of different types configured as Bragg pairs disposed on MTE1 and MBE 3 layers utilized for the upper and lower electrodes are presented in Table 3 below in which the acronyms have the same meanings as in Table 1.

TABLE 3
Properties of electrodes with Bragg pairs
on innermost metal electrode layers

| | Sample No. | | |
|---|---|---|---|
| | 10 | 11 | 12 |
| SV | SiO₂ | SiO₂ | SiO₂ |
| MTE3 | Ru | W | Ru |
| MTE2 | Al | Al | Al |
| MTE1 | Ru | W | W |
| PZL | AlScN | AlScN | AlScN |
| MBE3 | Ru | W | W |
| MBE2 | Al | Al | Al |
| MBE1 | Ru | W | Ru |
| MEM | SiO₂ | SiO₂ | SiO₂ |
| kₜ² (%) | 15.13 | 16.74 | 16.63 |
| Rₛ (Ω/□) | 0.06 | 0.06 | 0.06 |

The results of simulations of film bulk acoustic wave resonator structures with two metal layers of different types configured as Bragg pairs disposed on MBE 3 layers utilized for the lower electrodes and with upper electrodes formed from a single metal layer are presented in Table 4 below in which the acronyms have the same meanings as in Table 1.

TABLE 4
Properties of electrodes with Bragg pairs
on initial metal electrode layer

| | Sample No. | |
|---|---|---|
| | 13 | 14 |
| SV | SiO₂ | SiO₂ |
| MTE3 | | |
| MTE2 | | |
| MTE1 | Ru | W |
| PZL | AlScN | AlScN |
| MBE3 | Ru | W |
| MBE2 | Al | Al |
| MBE1 | Ru | W |
| MEM | SiO₂ | SiO₂ |
| kₜ² (%) | 18.0 | 19.7 |
| Rₛ (Ω/□) | 1.15 | 1.85 |

From the results above it can be seen that implementing top and/or bottom electrodes of a film bulk acoustic wave resonator as Bragg pairs can significantly reduce the resistance of the electrodes. Electrodes with single metal layers (Samples 1-5) exhibited resistances of between about 0.8 and 3.5Ω/□ (while electrodes including Bragg pairs in both the upper and lower electrodes (Samples 6-12) exhibited resistances of 0.06Ω/□, an improvement of more than an order of magnitude and the lowest observed resistances, with the kₜ² values reduced to still reasonable values in the low to mid teens from the low 20s for the single layer electrode samples (a reduction in kₜ² values of about 34% from Samples 1-5 on average). Samples 6-12 appeared to exhibit the best combination of kₜ² and resistance values among all samples, although these samples all utilized layers of Al, which may not be optimal in all embodiments due to the relatively low melting point of Al. Samples including each of the MTE1-MTE3 and MBE1-MBE3 layers (Samples 10-12) exhibited higher kₜ² values than samples with just two metal layers in the electrodes (Samples 6-9). Samples with the Bragg pairs only on a single side of the piezoelectric material layer (Samples 13 and 14) exhibited kₜ² values near 20% but with a resistance values 2× to 3× that of the samples with the triple layer top and bottom electrodes (Samples 10-12).

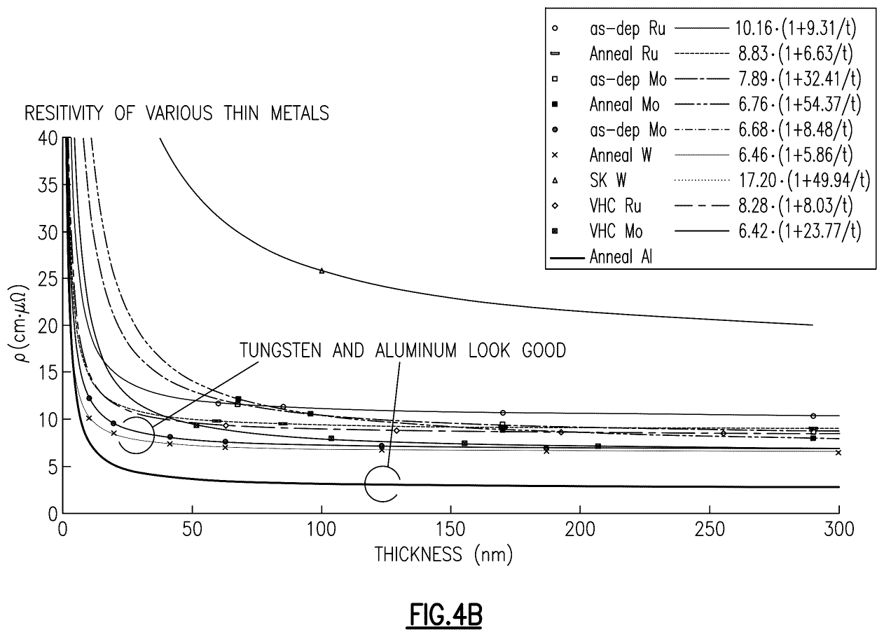

Another embodiment of an electrode structure for a BAW resonator including Bragg pairs is illustrated in FIG. 5. In this embodiment, there are two Bragg pairs disposed on each of the bottom and the top of the piezoelectric material layer, although in some alternative embodiments only a single Bragg pair or more than two Bragg pairs may be disposed on the top and/or bottom of the piezoelectric material layer. The Bragg pairs are formed of high and low impedance metals as disclosed above for the previously disclosed embodiments. In addition to the Bragg pairs outer layers of Al are disposed on each of the Bragg pairs on the opposite side of each of the Bragg pairs from the piezoelectric layer. The layers of Al may be thicker than the skin depth for Al to enhance conductivity of the Al layers. In various embodiments, the metals used in the Bragg pairs may have electrical resistivities higher than Al but may exhibit less mechanical energy loss to acoustic waves passing through them than Al would exhibit. The acoustic energy passing through the Bragg pairs is nearly completely reflected back toward the piezoelectric material layers at the locations when the Al layers are disposed on the Bragg layers so the Al layers would experience near zero strain. The Al layers disposed on the outside of the electrode structure on the Bragg pairs may thus provide increased conductivity to the electrode structure while having little to no effect on parameters such as the Q factor of the resonator. The outer layers of aluminum would typically not have any effect on the resonant frequency of the BAW so trimming of the BAW layers may be performed prior to deposition of the outer aluminum layers to obtain desired properties (e.g., resonant frequency) of the BAW resonator.

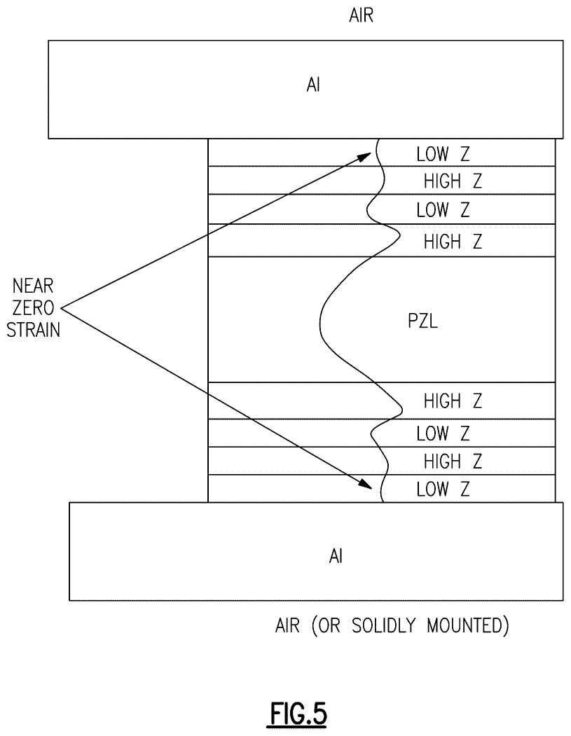

In some embodiments, multiple BAW resonators as disclosed herein may be combined into a filter, for example, an RF ladder filter schematically illustrated in FIG. 6 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include BAW devices or resonators, for example, duplexers, baluns, etc., may also be formed including examples of BAW resonators as disclosed herein.

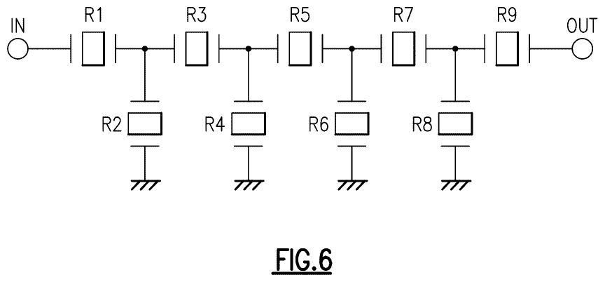

The acoustic wave devices discussed herein can be implemented in a variety of packaged modules. Some example packaged modules will now be discussed in which any suitable principles and advantages of the packaged acoustic wave devices discussed herein can be implemented. FIGS. 7, 8, and 9 are schematic block diagrams of illustrative packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example. FIG. 7 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

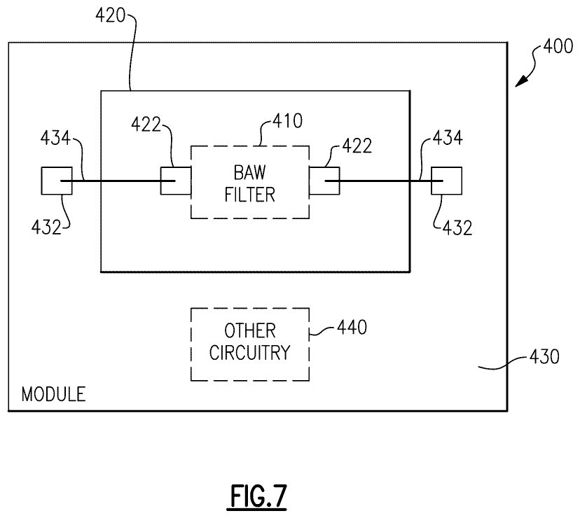

Referring to FIG. 8, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 8, however in other embodiments these components may be integrated into a common transceiver circuit or module. As will be appreciated by those skilled in the art, the front-end module 500 may include other components that are not illustrated in FIG. 8 including, but not limited to, switches, electromagnetic couplers, amplifiers, processors, and the like.

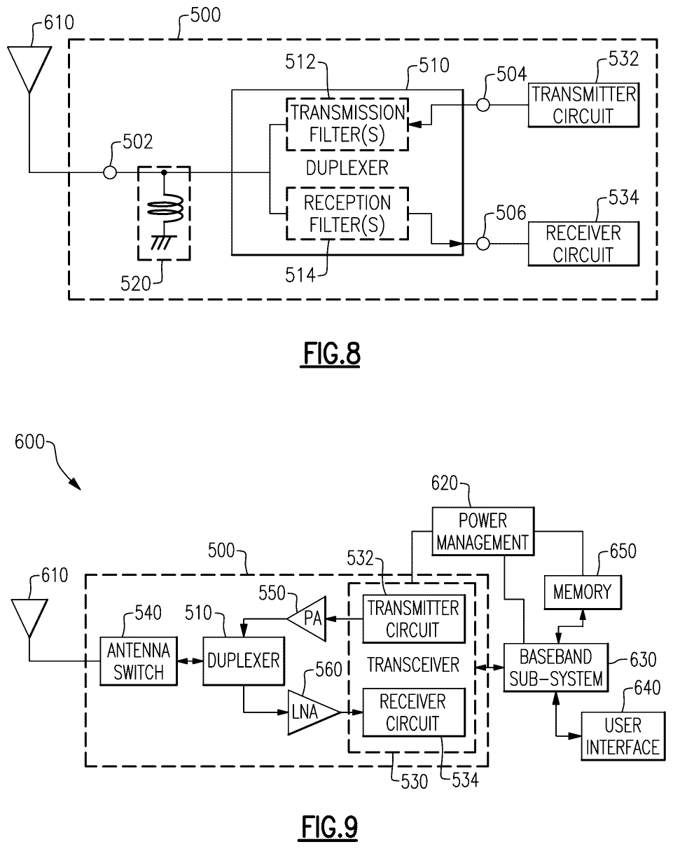

FIG. 9 is a block diagram of one example of a wireless device 600 including the antenna duplexer 510 shown in FIG. 8. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 8. The front-end module 500 includes the duplexer 510, as discussed above. In the example shown in FIG. 9 the front-end module 500 further includes an antenna switch 540, which can be configured to switch between different frequency bands or modes, such as transmit and receive modes, for example. In the example illustrated in FIG. 9, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 8.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 9, the front-end module 500 may further include a low noise amplifier module 560, which amplifies received signals from the antenna 610 and provides the amplified signals to the receiver circuit 534 of the transceiver 530.

The wireless device 600 of FIG. 9 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bulk acoustic wave resonator comprising:
a layer of piezoelectric material; and
one of a top electrode disposed on top of the layer of piezoelectric material or a bottom electrode disposed on a bottom of the layer of piezoelectric material, the one of the top electrode or the bottom electrode including a Bragg pair having alternating layers of a first metal and a second metal.

2. The bulk acoustic wave resonator of claim 1 wherein the Bragg pair is disposed directly on the one of the top of the layer of piezoelectric material or the bottom of the layer of piezoelectric material.

3. The bulk acoustic wave resonator of claim 2 wherein a first Bragg pair is disposed directly on the top of the layer of piezoelectric material and a second Bragg pair is disposed directly on the bottom of the layer of piezoelectric material.

4. The bulk acoustic wave resonator of claim 2 wherein the first metal layer of the Bragg pair is disposed directly on the one of the top of the layer of piezoelectric material or directly on the bottom of the layer of piezoelectric material and the second metal layer of the Bragg pair is disposed on a side of the first metal layer opposite the layer of piezoelectric material, the first metal layer having a higher acoustic impedance than the second metal layer.

5. The bulk acoustic wave resonator of claim 2 wherein the first metal layer of the Bragg pair is disposed directly on the one of the top of the layer of piezoelectric material or directly on the bottom of the layer of piezoelectric material and the second metal layer of the Bragg pair is disposed on a side of the first metal layer opposite the layer of piezoelectric material, the first metal layer having a lower acoustic impedance than the second metal layer.

6. The bulk acoustic wave resonator of claim 1 wherein the Bragg pair has an acoustic length of between about λ/3 and about 2λ/3, λ being a wavelength of a main acoustic wave generated in the bulk acoustic wave resonator at a series resonance frequency of the bulk acoustic wave resonator.

7. The bulk acoustic wave resonator of claim 1 wherein the layer of the first metal has a same acoustic length as the layer of the second metal.

8. The bulk acoustic wave resonator of claim 1 further comprising an innermost top metal electrode layer disposed directly on top of the piezoelectric material layer, the Bragg pair being a first Bragg pair disposed on top of the innermost top metal electrode layer, and an innermost bottom metal electrode layer disposed directly on a bottom surface of the piezoelectric material layer and a second Bragg pair disposed below the innermost bottom metal electrode layer.

9. The bulk acoustic wave resonator of claim 8 wherein the first layer of metal of the first Bragg pair is an intermediate top metal electrode layer and has a lower acoustic impedance than the innermost top metal electrode layer, and the second layer of metal of the first Bragg pair is an uppermost top metal electrode layer and has a higher acoustic impedance than the intermediate top metal electrode layer.

10. The bulk acoustic wave resonator of claim 9, wherein the uppermost top metal electrode layer is formed of a same metal as the innermost top metal electrode layer.

11. The bulk acoustic wave resonator of claim 9, wherein the uppermost top metal electrode layer is formed of a different metal than the innermost top metal electrode layer.

12. The bulk acoustic wave resonator of claim 8 wherein the first layer of metal of the second Bragg pair is an intermediate bottom metal electrode layer and has a lower acoustic impedance than the innermost bottom metal electrode layer, and the second layer of metal of the second Bragg pair is a lowermost bottom metal electrode layer and has a higher acoustic impedance than the intermediate bottom metal electrode layer.

13. The bulk acoustic wave resonator of claim 12, wherein the lowermost bottom metal electrode layer is formed of a same metal as the innermost bottom metal electrode layer.

14. The bulk acoustic wave resonator of claim 12, wherein the lowermost bottom metal electrode layer is formed of a different metal than the innermost bottom metal electrode layer.

15. The bulk acoustic wave resonator of claim 12 wherein each of the first and second metal layers of each of the first and second Bragg pairs have acoustic lengths greater than either of the innermost top metal electrode layer or the innermost bottom electrode layer.

16. The bulk acoustic wave resonator of claim 1 wherein the one of the top electrode or the bottom electrode includes a plurality of Bragg pairs, each of the plurality of Bragg pairs having alternating layers of a first metal and a second metal.

17. The bulk acoustic wave resonator of claim 16 wherein each of the top electrode and the bottom electrode includes a plurality of Bragg pairs, each of the plurality of Bragg pairs having alternating layers of a first metal and a second metal.

18. The bulk acoustic wave resonator of claim 17 wherein the one of the top electrode or the bottom electrode includes a layer of Al with a thickness greater than the skin depth of Al disposed on a side of the plurality of Bragg pairs opposite the layer of piezoelectric material.

19. An acoustic wave filter including the bulk acoustic wave resonator of claim 1.

20. An electronics module including the acoustic wave filter of claim 19.

21. An electronic device including the electronics module of claim 20.
